(19) United States
(12) Patent Application Publication
(10) Pub. No.: US 2024/0421758 A1
(43) Pub. Date: Dec. 19, 2024

(54) AWNING INCLUDING FLEXIBLE SOLAR CELLS, METHOD FOR MANUFACTURING THE SAME, AND RECREATIONAL VEHICLE

(71) Applicant: RNG INTERNATIONAL INC., Ontario, CA (US)

(72) Inventors: Jiang HUANG, Ontario, CA (US); Mike Xiaoli MA, Ontario, CA (US); Caicai XIONG, Ontario, CA (US)

(73) Assignee: RNG INTERNATIONAL INC., Ontario, CA (US)

(21) Appl. No.: 18/335,668

(22) Filed: Jun. 15, 2023

(51) Int. Cl. H02S 30/20; E04H 15/08; H01L 31/18; H02S 20/30

(52) U.S. Cl. CPC H02S 30/20; E04H 15/08; H01L 31/1876; H02S 20/30; B60P 3/343; H01L 31/0481; H01L 31/049

(57) ABSTRACT

The present disclosure provides an awning including flexible solar cells, a method of manufacturing the same, and a recreational vehicle. The awning comprises a reel, a tarpaulin adapted to be wound on the reel, and a plurality of flexible solar cells integrated on at least one surface of the tarpaulin. The tarpaulin is capable of being in a retracted state or an extended state. When the tarpaulin is in the extended state, the plurality of flexible solar cells have a first photoelectric conversion area exposed to the external environment, and when the tarpaulin is in the retracted state, the plurality of flexible solar cells have a second photoelectric conversion area exposed to the external environment. The area of the first photoelectric conversion area is greater than the area of the second photoelectric conversion area.

### TECHNICAL FIELD

The present disclosure relates to the field of outdoor sunshade technology, and in particular to an awning including flexible solar cells, a method for manufacturing the same, and a recreational vehicle.

### BACKGROUND

As a widely used sunshade structure, awnings can include solar cells, so as to generate electricity from sunlight while providing shade. Currently, most solar cells are glass-based solar panels, which are too heavy and too rigid. The awning not only needs to have sufficient strength to support the solar cells, but also faces a great challenge to be retracted and stored in a small space.

### SUMMARY

According to some embodiments of the present disclosure, an awning including flexible solar cells, a method for manufacturing the same, and a recreational vehicle are provided.

The awning includes a reel, a tarpaulin adapted to be wound on the reel, and a plurality of flexible solar cells integrated on at least one surface of the tarpaulin. The tarpaulin is capable of being in retracted state or extended state. When the tarpaulin is in the extended state, the plurality of flexible solar cells have a first photoelectric conversion area exposed to the external environment, and when the tarpaulin is in the retracted state, the plurality of flexible solar cells have a second photoelectric conversion area exposed to the external environment. The area of the first photoelectric conversion area is greater than the area of the second photoelectric conversion area.

The recreational vehicle includes a vehicle body and the aforementioned awning integrated with flexible solar cells. The awning is fixed to a vertical side wall of the vehicle body.

The method for manufacturing an awning integrated with flexible solar cells, includes: providing a tarpaulin and a plurality of flexible solar cells, and arranging the plurality of flexible solar cells on at least one surface of the tarpaulin; providing a reel, and winding the tarpaulin on the reel such that the tarpaulin is capable of being in retracted state or extended state. When the tarpaulin is in the extended state, the flexible solar cells have a first photoelectric conversion area exposed to the external environment, and when the tarpaulin is in the retracted state, the flexible solar cells have a second photoelectric conversion area exposed to the external environment. The area of the first photoelectric conversion area is greater than the area of the second photoelectric conversion area.

Details of one or more embodiments of the present disclosure are set forth in the following drawings and descriptions. Other objects, purposes and advantages will become apparent upon review of the following specification, drawings and claims.

### BRIEF DESCRIPTION OF THE DRAWINGS

In order to illustrate the embodiments of the present disclosure more clearly, the drawings used in the embodiments will be described briefly. Apparently, the following described drawings are merely for the embodiments of the present disclosure, and other drawings can be derived by those of ordinary skill in the art without any creative effort.

FIG. 1 is a schematic view of an awning in retracted state according to an embodiment of the present disclosure.

FIG. 2 is a schematic view of the awning in extended state according to an embodiment of the present disclosure.

FIG. 3 is a schematic view of a flexible solar cell according to an embodiment of the present disclosure.

FIG. 4 is a schematic view of an awning in retracted state according to another embodiment of the present disclosure.

FIG. 5 is a cross-sectional view of a solar cell module along a first direction according to an embodiment of the present disclosure.

FIG. 6 is a cross-sectional view of the solar cell module along a second direction according to an embodiment of the present disclosure.

FIG. 7 is a cross-sectional view of the solar cell module along a third direction according to an embodiment of the present disclosure.

FIG. 8 is a perspective view of a reel according to an embodiment of the present disclosure.

FIG. 9 is a schematic side view of an awning in retracted state according to another embodiment of the present disclosure.

FIG. 10 is a schematic perspective view of an awning in retracted state according to another embodiment of the present disclosure.

FIG. 11 is a schematic view of an awning in retracted state according to another embodiment of the present disclosure.

FIG. 12 is a schematic partial view of a recreational vehicle including an awning in retracted state according to an embodiment of the present disclosure.

FIG. 13 is a schematic partial view of a recreational vehicle including an awning in extended state according to an embodiment of the present disclosure.

### DETAILED DESCRIPTION OF THE EMBODIMENTS

In order to make the above objects, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuth or position relationship shown in the attached drawings, which are only for the convenience of describing the present disclosure and simplifying the description, rather than indicating or implying that the device or element must have a specific azimuth, be constructed and operated in a specific azimuth, so such terms cannot be understood as a limitation of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “multiple” means at least two, such as two, three, etc., unless otherwise expressly and specifically defined.

In the present invention, unless otherwise expressly specified and limited, the terms “mount”, “connect”, “contact”, “fix” and other terms should be understood in a broad sense, for example, they can be fixed connections, removable connections, or integrated. They can be mechanical connection or electrical connection. They can be directly connected or indirectly connected through an intermediate medium. They can be the connection within two elements or the interaction relationship between two elements, unless otherwise expressly limited. For those skilled in the art, the specific meaning of the above terms in the present disclosure can be understood according to the specific situation.

In the present invention, unless otherwise expressly specified and limited, the first feature “above” or “below” the second feature may be in direct contact with the first and second features, or the first and second features may be in indirect contact through an intermediate medium. Moreover, the first feature is “above” the second feature, but the first feature is directly above or diagonally above the second feature, or it only means that the horizontal height of the first feature is higher than the second feature. The first feature is “below” of the second feature, which can mean that the first feature is directly below or obliquely below the second feature, or simply that the horizontal height of the first feature is less than that of the second feature.

It should be noted that when an element is called “fixed to” or “provided on” another element, it can be directly on another element or there can be a centered element. When an element is considered to be “connected” to another element, it can be directly connected to another element or there may be intermediate elements at the same time. The terms “vertical”, “horizontal”, “up”, “down”, “left”, “right” and similar expressions used herein are for the purpose of illustration only and do not represent the only embodiment.

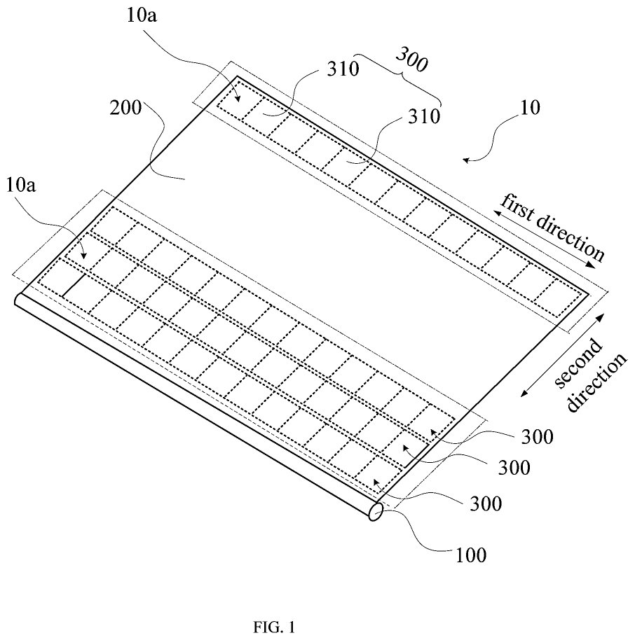

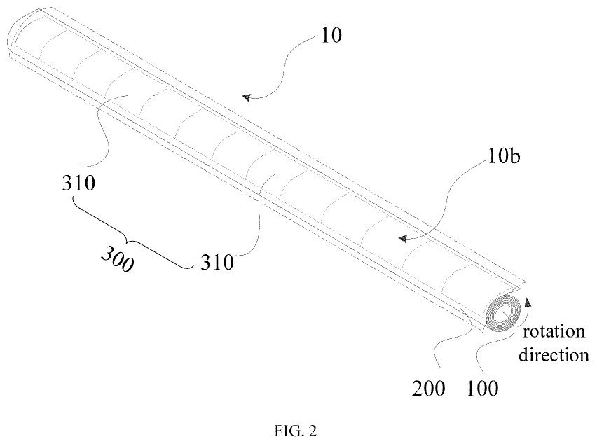

FIG. 1 is a schematic view of an awning 10 in retracted state according to an embodiment of the present disclosure, and FIG. 2 is a schematic view of the awning 10 in extended state according to an embodiment of the present disclosure. Referring to FIG. 1 and FIG. 2, the awning 10 includes a reel 100, a tarpaulin 200, and a plurality of flexible solar cells 310. The tarpaulin 200 is adapted to be wound on the reel 100, and the tarpaulin 200 can be in retracted state or extended state. The flexible solar cells 310 are integrated on at least one surface of the tarpaulin 200.

The awning 10 may be mounted on a wall of a building, a sidewall of a recreational vehicle, or other mounting surfaces to shade and generate electricity.

The flexible solar cells 310 are made of a flexible material, which enables the flexible solar cells 310 to be bent. Due to the flexibility of the flexible solar cells 310, the awning 10 can be bent and wound with a smaller radius of curvature, for example, the tarpaulin 200 can be wound on a reel 100 with a diameter less than 4 inches, and the awning 10 can be a columnar structure with a diameter of 2 inches to 12 inches when the tarpaulin 200 is fully retracted, which greatly reduces a space occupied by the awning 10 and can also be aesthetically accepted to users. In order to further improve the flexibility of the awning 10 so that the awning 10 can be bent and wound with a smaller radius of curvature, the tarpaulin 200 can be a fabric made of inorganic fibers or organic fibers. The inorganic fibers are glass fibers, quartz glass fibers, boron fibers or ceramic fibers, and the organic fibers are polyester, acrylic, nylon or polypropylene fibers.

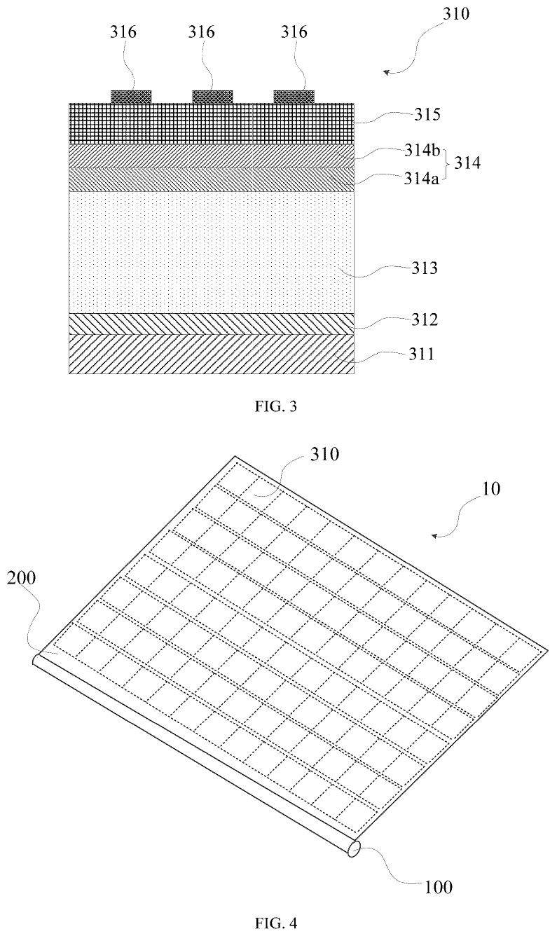

Referring to FIG. 3, the flexible solar cell 310 includes a conductive substrate 311, a back electrode layer 312, a photoelectric conversion layer 313, a buffer layer 314, a transparent conductive layer 315, and a plurality of extraction electrodes 316, which are stacked in sequence.

The conductive substrate 311 may be stainless steel foil, titanium foil, copper foil, aluminum foil, or beryllium foil, or can be a polymer film coated with a conductive oxide or metal layer, such as a polyimide film. The back electrode layer 312 may be made of a conductive metal material, such as Ti, Ni, Cr, Ag, Al, Cu, Au, Mo, ITO, ZnO, SnO, etc. The photoelectric conversion layer 313 includes at least four elements of Cu, In, Ga and Se, the atomic percentage of Cu is 10% to 30%, the atomic percentages of In and Ga are both 1% to 20%, and the atomic percentage of Se is 20% to 60%. The buffer layer 314 may have n-type conductivity and form a p-n junction with the photoelectric conversion layer 313. In order to improve a conductivity of the p-n junction between the buffer layer 314 and the photoelectric conversion layer 313, the buffer layer 314 may be a multilayer structure, for example, as shown in FIG. 3, the buffer layer 314 includes a CdS buffer layer 314a with a thickness of 50 nm and a ZnO buffer layer 314b with a thickness of 50 nm. The transparent conductive layer 315 includes one or more transparent conductive oxides (TCO), such as zinc oxide, aluminum-doped zinc oxide (AZO), indium tin oxide (ITO) and gallium-doped zinc oxide, and a thickness of the transparent conductive layer 315 may be in a range of 100 nm to 2000 nm, so as to ensure light transmission and conductivity. The extraction electrode 316 and the conductive substrate 311 are made of the same material, and the extraction electrodes 316 may be formed on the transparent conductive layer 315 in an array arrangement.

Further, referring to FIG. 1, when the tarpaulin 200 is in the extended state, the flexible solar cells 310 have a first photoelectric conversion area 10a exposed to the external environment. Referring to FIG. 2, when the tarpaulin 200 is in the retracted state, the flexible solar cells 310 have a second photoelectric conversion area 10b exposed to the external environment, and the area of the first photoelectric conversion area 10a is greater than the area of the second photoelectric conversion area 10b. The first photoelectric conversion area 10a refers to a region on the awning 10 where photoelectric conversion layers of the flexible solar cells 310 within the dotted line frame in FIG. 1 are located. The second photoelectric conversion area 10b refers to a region on the awning 10 where the photoelectric conversion layers of the flexible solar cells 310 within the dotted line frame in FIG. 2 are located.

In an embodiment, as shown in FIG. 1, a part of a surface of the tarpaulin 200 is covered with the flexible solar cells 310. In another embodiment, as shown in FIG. 4, the entire surface of the tarpaulin 200 is covered with the flexible solar cells 310, so as to improve the power generation capacity of the awning 10.

When the tarpaulin 200 of the awning 10 is extended from the reel 100, the first photoelectric conversion area 10a of the flexible solar cell 310 can be exposed to the external environment and irradiated by sunlight, and the first photoelectric conversion area 10a can convert the received sunlight into electrical energy to generate electricity. Similarly, when the tarpaulin 200 of the awning 10 is retracted onto the reel 100, the second photoelectric conversion area 10b of the flexible solar cell 310 can be exposed to the external environment and irradiated by sunlight, and the second photoelectric conversion area 10b can convert the received sunlight into electrical energy to generate electricity. Though the area of the first photoelectric conversion area 10a is greater than that of the second photoelectric conversion area 10b, the awning 10 can generate electricity no matter whether the awning 10 is extended or retracted. Especially when the recreational vehicle is in motion, although the awning 10 is in the retracted state, solar energy can still be effectively used to generate electricity, which further improves the power generation capacity of the awning 10.

The first photoelectric conversion area 10a and the second photoelectric conversion area 10b are located on the same surface of the tarpaulin 200. For example, both the first photoelectric conversion area 10a and the second photoelectric conversion area 10b are located on an upper surface of the tarpaulin 200 in the extended state. In this case, the first photoelectric conversion area 10a includes the second photoelectric conversion area 10b. When the tarpaulin 200 is in the extended state, the second photoelectric conversion area 10b as a part of the first photoelectric conversion area 10a can also be irradiated by sunlight to generate electricity, so that the second photoelectric conversion areas 10b can generate electricity no matter the tarpaulin 200 is in the extended state or the retracted state, which can improve the utilization efficiency of the flexible solar cells 310.

It should be noted that, in order to ensure that the second photoelectric conversion area 10b can be exposed to the external environment when the tarpaulin 200 is retracted, the reel 100 is driven to rotate in a rotation direction shown in FIG. 2 to retract the tarpaulin 200.

In other embodiments, the first photoelectric conversion area 10a and the second photoelectric conversion area 10b are located on different surfaces of the tarpaulin 200. It should be noted that, in order to ensure that the second photoelectric conversion area 10b can be exposed to the external environment when the tarpaulin 200 is in the retracted state, the reel 100 can be driven to rotate in a direction opposite to that shown in FIG. 2 to retract the tarpaulin 200.

Since the flexible solar cells 310 are usually arranged on the awning 10 in form of solar cell modules 300, the encapsulation material of the solar cell module 300 may affect the flexibility of the awning 10, while a thickness of the encapsulation layer is related to the service life and rated voltage of the awning 10. That is, the longer the designed service life of the awning 10 and the higher the rated voltage, the thicker the encapsulation layer of the solar cell module 300. Therefore, in order to ensure that the awning 10 has sufficient flexibility to be wound on the small-diameter reel 100, the present disclosure is designed for solar products with a service life of 1 to 15 years and a rated voltage of less than 300V, not for conventional solar products with a service life of more than 25 years and a rated voltage higher than 600V, which meets the requirements of IEC 63163.

Specifically, referring to FIG. 1 and FIG. 2, the flexible solar cells 310 are arranged on at least one surface of the tarpaulin 200 along a first direction and a second direction perpendicular to the first direction. The flexible solar cells 310 adjacent in the first direction are connected in series to each other to form at least one solar cell module 300. The solar cell modules 300 adjacent in the second direction are connected in parallel with each other. The first direction is an axial direction of the reel 100, and the second direction is a direction in which the tarpaulin 200 is extended or retracted. When the tarpaulin 200 is not fully extended or retracted, the solar cell modules 300 exposed to the external environment will not be affected by the retracted solar cell modules 300 and can generate electricity normally.

It should be noted that when the tarpaulin 200 is retracted, at least one solar cell module 300 is fully or partially exposed to the external environment to form the second photoelectric conversion area 10b. That is, when the tarpaulin 200 is in the retracted state, at least one solar cell module 300 in the second photoelectric conversion area 10b is fully exposed to the external environment, so as to ensure that the second photoelectric conversion area 10b of the flexible solar cell 310 can generate electricity normally.

The number of rows of the solar cell modules 300 in the second direction can be determined according to a solar coverage requirement and a size of the awning 10. For example, when the solar cell modules 300 are arranged on the same surface of the tarpaulin 200, the number of rows of the solar cell modules 300 in the second direction may be greater than or equal to 2 and less than or equal to 6.

Two adjacent rows of solar cell modules 300 are aligned in the second direction, so as to meet the size and electrical requirements of the awning 10. In the second direction, each row of solar cell modules 300 may include one or more solar cell modules 300.

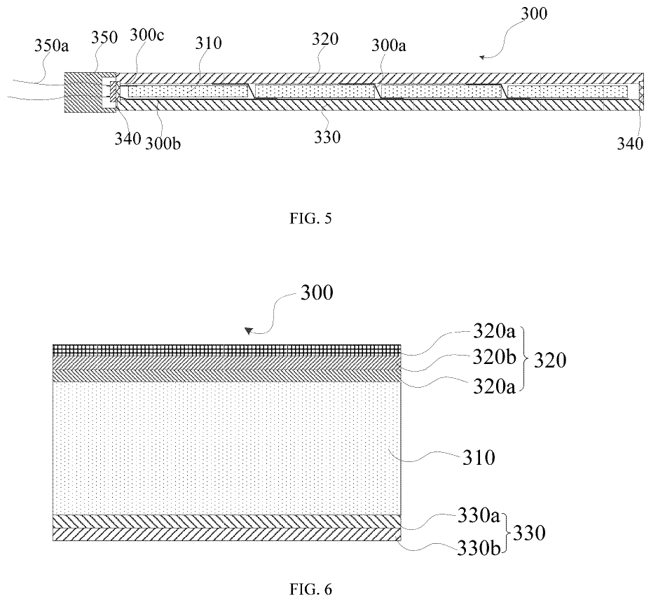

Referring to FIG. 5, the flexible solar cells 310 are encapsulated by a back sheet 330, a front sheet 320, and an edge sealing member 340 to form the solar cell module 300. The back sheet 330 may be laminated on a surface of the tarpaulin 200 in an adhesive-free or adhesive manner, so that the flexible solar cell 310 can be used as a part of the awning 10.

Specifically, referring to FIG. 6, the front plate 320 may include a polymer film 321, a first PET film layer 322, and a first bonding layer 323 that are stacked in sequence. The back sheet 330 includes a second bonding layer and a second PET film layer stacked in sequence, and the flexible solar cell 310 is disposed between the first bonding layer 331 and the second bonding layer 332. Since both the PET film layer and the bonding layer have a significant impact on the flexibility and bendability of the solar cell module 300, the sum of the thicknesses of the first PET film layer 322 and the second PET film layer is less than or equal to 150 microns, and the sum of the thicknesses of the first bonding layer 323 and the second bonding layer is less than or equal to 200 microns.

The polymer film 321 has good cut resistance and scratch resistance, which can protect the flexible solar cell 310. The polymer film 321 can be a film made of an organic polymer, such as polyvinylidene fluoride (PVDF) or ethylene-tetrafluoroethylene copolymer (ETFE), and a thickness of the polymer film 321 may be 25 to 200 microns. The first bonding layer 323 and the second bonding layer are configured to bond the front sheet 320 and the back sheet 330 to the flexible solar cell 310, respectively. The first bonding layer 323 and the second bonding layer may be made of at least one of polyvinyl butyral, polyolefin, ethylene-vinyl acetate copolymer, fluorine resin, silicone resin, or acrylic resin.

The edge sealing member 340 may be made from one or more organic or inorganic materials that have a low inherent water vapor transmission rate.

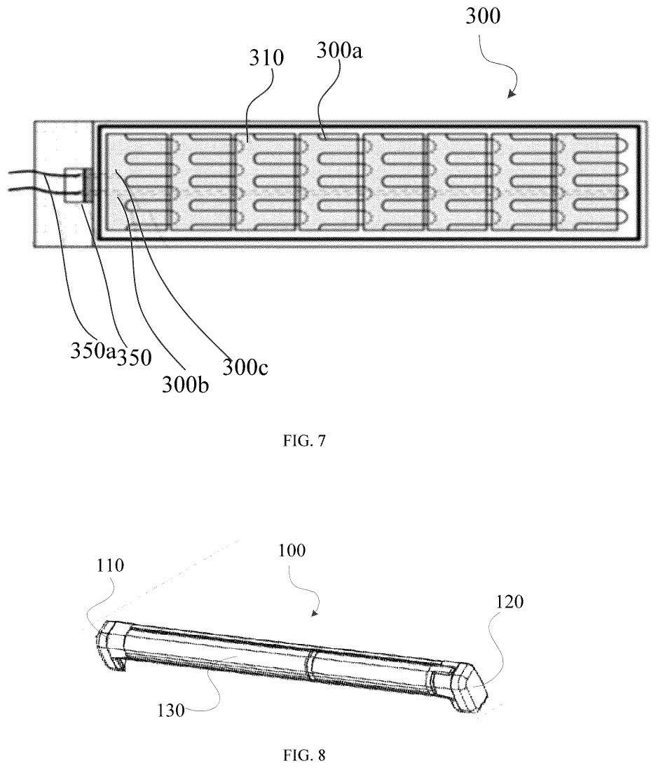

Further, referring to FIG. 5 and FIG. 7, the solar cell module 300 may further include an external electrical connector 350, and the flexible solar cells 310 in the solar cell module 300 are connected to the external electrical connector 350 when being connected in series. The current generated by the solar cell module 300 can be transmitted to components outside the solar cell module 300, such as other solar cell modules 300, an inverter or a power grid, through lead wires 350a on the external connector 350.

Adjacent flexible solar cells 310 in the same solar cell module 300 are connected in series through at least one wire. The flexible solar cells 310 are connected in series through the wire, which can not only simplify the structure of the solar cell module 300, but also facilitate the connection of the adjacent flexible solar cells 310.

Specifically, referring to FIG. 5 and FIG. 7, the front side of a flexible solar cell 310 is connected in series to the back side of an adjacent flexible solar cell 310 in the same solar cell module 300 through a wire 300a. As shown in FIG. 3, the front side of the flexible solar cell 310 is a surface of the extraction electrode 316 away from the transparent conductive layer 315, and the back side of the flexible solar cell 310 is a surface of the conductive substrate 311 away from the back electrode layer 312.

Referring to FIG. 5 and FIG. 7, the solar cell module 300 is further provided with a first bus wire group 300b and a second bus wire group 300c, and both the first bus wire group 300b and the second bus wire group 300c are connected to the external connector 350. The first wire group 300b is connected to the back sides of all flexible solar cells 310 except the first and last flexible solar cells 310 of the flexible solar cells 310 connected in series. The second bus wire group 300a is connected to the front sides of the first and last flexible solar cells 310. The first bus wire group 300b and the second bus wire group 300c may be solid metal strips or interlaced metal strands.

Each solar cell module 300 on the tarpaulin 200 can be connected in series to a photovoltaic power optimizer. The photovoltaic power optimizer can solve the problem of reduced power generation of the solar cell module 300 caused by shadow shading, orientation difference or inconsistent attenuation, thereby enabling maximum power output and online monitoring of solar cell module 300.

Referring to FIG. 8, the reel 100 includes a first end cover 110, a second end cover 120, an outer tube 130, and a rotating shaft (not shown in the figure). The first end cover 110 and the second end cover 120 are disposed on two ends of the reel 100 in the axial direction thereof, respectively. The rotating shaft includes a first end and a second end opposite to the first end, the first end of the rotating shaft is rotatably received in the first end cover 110, and the second end of the rotating shaft is rotatably received in the second end cover 120. The outer tube 130 is sleeved on the rotating shaft and connected to an end of the tarpaulin 200. When the rotating shaft rotates, the outer tube 130 is driven to rotate, so that the tarpaulin 200 can be retracted and extended.

Further, the reel 100 further includes a driving assembly (not shown in the figures) disposed in the first end cover 110. The driving assembly may include a driving wheel and a motor, the driving wheel is connected to an output shaft of the motor, and the driving wheel is disposed inside the rotating shaft. The driving wheel may be assembled in the rotating shaft through a cooperation of a slot and a buckle. The flexible solar cells 310 or other power source supplies power to the motor.

Further, the reel 100 further includes a torsion spring (not shown in the figures). The torsion spring includes a first end and a second end opposite to the first end, the first end of the torsion spring is disposed in the rotating shaft, and the second end of the torsion spring is disposed in the first end cover 110. The torsion spring is configured to provide a force to the rotating shaft to retract the tarpaulin 200.

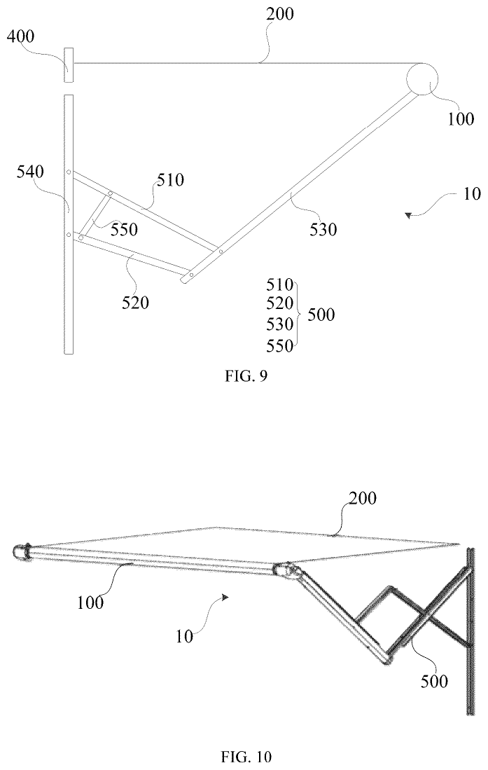

FIG. 9 is a schematic side view of an awning 10 in retracted state according to another embodiment of the present disclosure. The awning 10 further includes a fixing bracket 400 and a retractable bracket 500, the fixing bracket 400 is configured to fix the awning 10 to a mounting surface, and the retractable bracket 500 is configured to unfold or retract the tarpaulin 200. The tarpaulin 200 includes a first end and a second end opposite to the first end, the first end of the tarpaulin 200 is connected to the fixing bracket 400, and the second end of the tarpaulin 200 is connected to the reel 100. During the extension of the retractable bracket 500, the tarpaulin 200 can be extended under the rotation of the reel 100. In other embodiments, the first end of the tarpaulin 200 is connected to the reel 100, and the second end of the tarpaulin 200 is connected to the retractable bracket 500.

Two retractable brackets 500 may be provided, one retractable bracket 500 is connected to the first end cover 110 of the reel 100, and the other retractable bracket 500 is connected to the second end cover 120 of the reel 100.

The retractable bracket 500 may be a link structure, and the retractable bracket 500 can be extended or retracted through the hinged connection between the rods of the link structure. FIG. 9 shows a non-intersecting link structure, and FIG. 10 shows an intersecting link structure. Referring to FIG. 9, the non-intersecting link structure may include a first rod 510, a second rod 520, and a third rod 530. The first rod 510 and the second rod 520 are located in the same plane, and the first rod 510, the second rod 520 and the third rod 530 each includes a first end and a second end opposite to the first end. The first ends of the first rod 510 and the second rod 520 are hinged to the mounting surface through the mounting bracket 540, the second ends of the first rod 510 and the second rod 520 are hinged to the first end of the third rod 530, and the second end of the second rod 510 is hinged to the first end of the third rod 530. The second ends of at least two third rods 530 are rotatably connected to the first end cover 110 and the second end cover 120 of the reel 100, respectively. Optionally, the non-intersecting link structure may further include a reinforcing rod 550 connected to the first rod 510 and the second rod 520.

The retractable bracket 500 can also be a retractable rod structure, which can include a first retractable rod arranged horizontally and a second retractable rod arranged obliquely. The first retractable rod and the second retractable rod each include a first end and a second end opposite to the first end. The first ends of both the first retractable rod and the second retractable rod are fixed to the mounting surface, and the second ends of both the first retractable rod and the second retractable rod are fixed to the reel 100. Both the first retractable rod and the second retractable rod are formed by nesting a plurality of pipes in sequence, and the telescoping of the first retractable rod or the second retractable rod is achieved by extending the pipe from the adjacent pipe or retracting the pipe into the adjacent pipe.

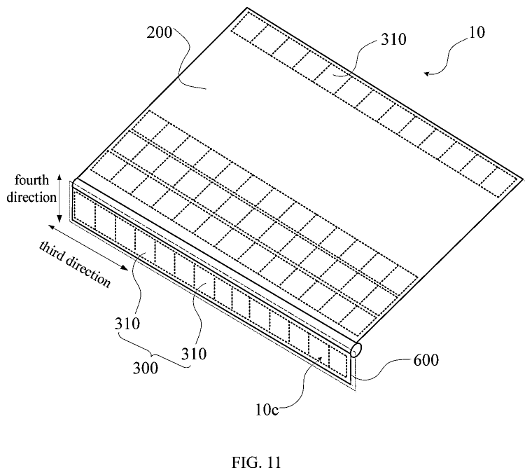

On the basis of the awning shown in FIG. 1, FIG. 11 shows another embodiment of the awning 10 of the present disclosure. Referring to FIG. 11, the awning 10 further includes a decorative curtain 600. The decorative curtain 600 is disposed along the axial direction of the reel 100 and connected to the first end cover and the second end cover of the reel 100. The decorative curtain 600 plays a role of decoration. In other embodiments, the decorative curtain 600 may also be fixed to the retractable bracket 500 or the second end of the tarpaulin 200.

Referring to FIG. 11, at least one flexible solar cell 310 is disposed on a surface of the decorative curtain 600, and when the tarpaulin 200 is in the extended state or the retracted state, the flexible solar cells 310 further have a third photoelectric conversion area 10c exposed to the external environment. Regardless of whether the awning 10 is extended or retracted, the decorative curtain 600 is always exposed to the external environment, so that the flexible solar cells 310 on the decorative curtain 600 can be irradiated by sunlight to generate electricity. The third photoelectric conversion area 10c refers to a region on the decorative curtain 600 where the photoelectric conversion layers of the flexible solar cells 310 within the dotted line frame in FIG. 10 are located.

In other embodiments, when the tarpaulin 200 is retracted, the decorative curtain 600 can also be retracted through the reel 100, and the flexible solar cells 310 on the decorative curtain 600 will no longer generate electricity.

Referring to FIG. 11, the flexible solar cells 310 are further arranged in the third photoelectric conversion area 10c along a third direction and a fourth direction perpendicular to the third direction. The flexible solar cells 310 adjacent in the third direction are connected in series to each other to form at least one solar cell module 300, and the solar cell modules 300 adjacent in the fourth direction are connected in parallel to each other. When the decorative curtain 600 is partially shaded, the shaded solar cell modules 300 do not generate electricity, while the unshaded solar cell modules 300 can generate electricity normally. The third direction may be parallel to the first direction, and the fourth direction is a vertical direction.

The structure of the solar cell module 300 on the decorative curtain 600 and the connection method of the flexible solar cells 310 therein can be the same as that of the other solar cell modules 300 on the tarpaulin 200, and will not be repeated herein.

The solar cell modules 300 on the decorative curtain 600 may also be connected in series to photovoltaic power optimizers.

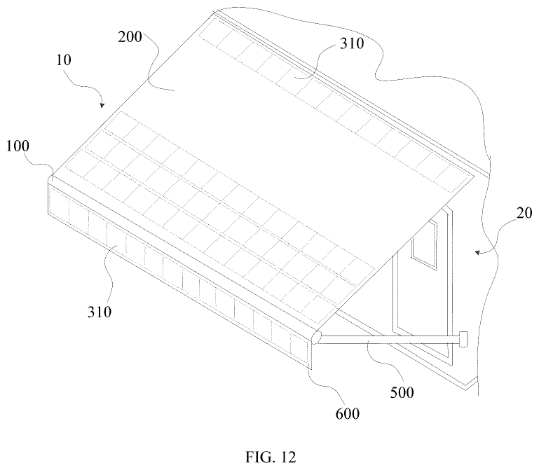

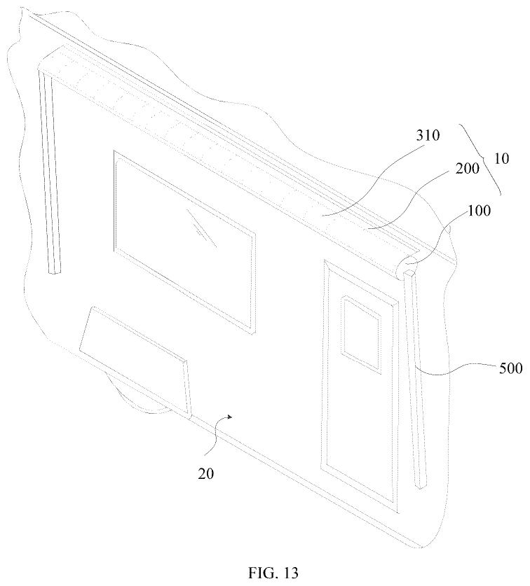

FIG. 12 is a partial schematic view of a recreational vehicle with the awning 10 in retracted state according to an embodiment of the present disclosure, and FIG. 13 is a partial schematic view of a recreational vehicle with the awning 10 in extended state according to an embodiment of the present disclosure. Referring to FIG. 12 and FIG. 13, the recreational vehicle includes a vehicle body 20 and the awning 10 including the flexible solar cell 310 as described above, and the awning 10 is fixed to a vertical side wall of the vehicle body 20.

The recreational vehicle further includes an energy storage device and an electrical device, the energy storage device is connected to the flexible solar cells 310 of the awning 10, and the electrical device is connected to the energy storage device. The electrical device may be a lighting device, such as an atmosphere light suspended on the awning 10, and the electrical device may also be a display device.

A method for manufacturing the awning 10 including the flexible solar cells 310 is provided according to another embodiment of the present disclosure, which includes the following steps.

Step S100, the tarpaulin 200 and a plurality of flexible solar cells 310 are provided, and the flexible solar cells 310 are arranged on at least one surface of the tarpaulin 200.

Specifically, the flexible solar cells 310 are divided into a plurality of groups, the flexible solar cells 310 in each group are connected in series and encapsulated by the back sheet 330 and the front sheet 320 to form the solar cell module 300. Then, the solar cell modules 300 are arranged on the tarpaulin 200 along the first direction and the second direction perpendicular to the first direction, and the back sheet 330 of the solar cell module 300 is laminated on the tarpaulin 200 by thermal fusing.

Step S200, the reel 100 is provided, and the tarpaulin 200 is wound on the reel 100, such that the tarpaulin 200 can be in retracted state or extended state. When the tarpaulin 200 is in the extended state, the flexible solar cells 310 have the first photoelectric conversion area 10a exposed to the external environment, and when the tarpaulin 200 is in the retracted state, the flexible solar cells 310 have the second photoelectric conversion area 10b exposed to the external environment. The area of the first photoelectric conversion area 10a is greater than that of the second photoelectric conversion area 10b.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

What is claimed is:

1. An awning, comprising:
a reel;
a tarpaulin adapted to be wound on the reel and capable of being in a retracted state or an extended state; and
a plurality of flexible solar cells integrated on at least one surface of the tarpaulin;
wherein when the tarpaulin is in the extended state, the plurality of flexible solar cells have a first photoelectric conversion area exposed to the external environment, when the tarpaulin is in the retracted state, the plurality of flexible solar cells have a second photoelectric conversion area exposed to the external environment, and the area of the first photoelectric conversion area is greater than the area of the second photoelectric conversion area.

2. The awning according to claim 1, wherein the first photoelectric conversion area and the second photoelectric conversion area are located on the same surface of the tarpaulin, and the first photoelectric conversion area comprises the second photoelectric conversion area.

3. The awning according to claim 1, wherein the plurality of flexible solar cells are arranged along a first direction and a second direction perpendicular to the first direction, flexible solar cells adjacent in the first direction of the plurality of flexible solar cells are connected in series to each other to form at least one solar cell module.

4. The awning according to claim 3, wherein the at least one solar cell module comprises a plurality of solar cell modules adjacent in the second direction connected in parallel to each other, adjacent flexible solar cells in the same solar cell module are connected in series through at least one wire.

5. The awning according to claim 4, wherein a front side of a first flexible solar cell of the adjacent flexible solar cells is connected in series to a back side of a second flexible solar cell of the adjacent flexible solar cells adjacent to first flexible solar cell in the same solar cell module through the wire.

6. The awning according to claim 5, wherein each of the plurality of flexible solar cells comprises a conductive substrate, a photoelectric conversion layer, a buffer layer, a transparent conductive layer, and an extraction electrode stacked in sequence, and the conductive substrate or the extraction electrode is connected to the wire.

7. The awning according to claim 3, wherein the first direction is the axial direction of the reel, and the second direction is a direction in which the tarpaulin is to be extended or retracted.

8. The awning according to claim 7, wherein when the tarpaulin is in the retracted state, at least one of the plurality of first solar cell modules is fully or partially exposed to the external environment to form the second photoelectric conversion area.

9. The awning according to claim 3, further comprising a plurality of photovoltaic power optimizers, wherein each solar cell module is connected in series to a corresponding photovoltaic power optimizer.

10. The awning according to claim 1, further comprising a back sheet and a front sheet stacked with each other, wherein the plurality of flexible solar cells are encapsulated between the back sheet and the front sheet, and the back sheet is laminated on the tarpaulin.

11. The awning according to claim 10, wherein the front sheet comprises a polymer film, a first PET film layer, and a first bonding layer that are stacked in sequence, the back sheet comprises a second bonding layer and a second PET film layer stacked in sequence, and the flexible solar cell is disposed between the first bonding layer and the second bonding layer;
the sum of the thicknesses of the first PET film layer and the second PET film layer is less than or equal to 150 microns, and the sum of the thicknesses of the first bonding layer and the second bonding layer is less than or equal to 200 microns.

12. The awning according to claim 10, wherein the material of the tarpaulin comprises inorganic fibers or organic fibers.

13. The awning according to claim 1, further comprising:
a fixing bracket configured to fix the awning to a mounting surface; and
a retractable bracket configured to extend or retract the tarpaulin;
wherein the tarpaulin comprises a first end and a second end opposite to the first end, the first end of the tarpaulin is connected to the fixing bracket, and the second end of the tarpaulin is connected to the reel, or the first end of the tarpaulin is connected to the reel, and the second end of the tarpaulin is connected to the retractable bracket.

14. The awning of claim 13, further comprising:
a decorative curtain fixed to the second end of the tarpaulin, the reel, or the retractable bracket; and
at least one additional flexible solar cell disposed on a surface of the decorative curtain,
wherein when the tarpaulin is in the extended state or the retracted state, the at least one additional flexible solar cell further form a third photoelectric conversion area exposed to the external environment.

15. The awning according to claim 14, wherein the at least one additional flexible solar cell is a plurality of additional flexible solar cells forming the third photoelectric conversion area, the plurality of additional flexible solar cells are arranged along a third direction and a fourth direction perpendicular to the third direction, additional flexible solar cells adjacent in the third direction of the plurality of additional flexible solar cells are connected in series to each other to form additional solar cell modules, and the additional solar cell modules adjacent in the fourth direction are connected in parallel to each other.

16. A recreational vehicle, comprising:
a vehicle body; and
the awning according to claim 1, wherein the awning is fixed to a vertical side wall of the vehicle body.

17. The recreational vehicle of claim 16, further comprising:
an energy storage device connected to the plurality of flexible solar cells of the awning; and
an electrical device connected to the energy storage device.

18. A method for manufacturing an awning including flexible solar cells, comprising:
providing a tarpaulin and a plurality of flexible solar cells, and arranging the plurality of flexible solar cells on at least one surface of the tarpaulin; and
providing a reel, and winding the tarpaulin on the reel such that the tarpaulin is capable of being in retracted state or extended state;
wherein when the tarpaulin is in the extended state, the flexible solar cells have a first photoelectric conversion area exposed to the external environment, when the tarpaulin is in the retracted state, the flexible solar cells have a second photoelectric conversion area exposed to the external environment, and the area of the first photoelectric conversion area is greater than the area of the second photoelectric conversion area.

19. The method according to claim 18, wherein before arranging the flexible solar cells on at least one surface of the tarpaulin, the method further comprises:
dividing the plurality of the solar cells into a plurality of groups, and connecting the flexible solar cells in each group in series and encapsulating the flexible solar cells in each group through a back sheet and a front sheet to form each of a plurality of solar cell modules; and
the arranging the plurality of flexible solar cells on at least one surface of the tarpaulin comprises:
arranging the plurality of solar cell modules on the tarpaulin along a first direction and a second direction perpendicular to the first direction, and laminating the back sheet on the tarpaulin.

20. The preparation method according to claim 19, wherein the back sheet is laminated on the tarpaulin by thermal fusing.
